(19) United States
(12) Patent Application Publication
(10) Pub. No.: US 2024/0417593 A1
(43) Pub. Date: Dec. 19, 2024

(54) SLURRY COMPOSITION FOR CHEMICAL MECHANICAL POLISHING AND METHOD OF MANUFACTURING SEMICONDUCTOR DEVICE

(71) Applicant: Samsung Electronics Co., Ltd., Suwon-si (KR)

(72) Inventors: Woosung Jeon, Suwon-si (KR); Yongtae Park, Suwon-si (KR); Doyoon Kim, Suwon-si (KR); Jaehoon Ryu, Suwon-si (KR); Sunjae Jang, Suwon-si (KR); Sungsik Jo, Suwon-si (KR)

(21) Appl. No.: 18/596,020

(22) Filed: Mar. 5, 2024

(30) Foreign Application Priority Data
Jun. 19, 2023 (KR) 10-2023-0078172

(51) Int. Cl. C09G 1/02

(52) U.S. Cl. CPC C09G 1/02

(57) ABSTRACT

Provided is a slurry composition for chemical mechanical polishing (CMP) including an organic abrasive material that includes a supramolecular compound (e.g., supramolecular assembly), an analog thereof, or a derivative thereof. The slurry composition for chemical mechanical polishing may reduce or prevent CMP-induced defects, thereby reducing or suppressing product defects with a higher polishing selectivity.

### CROSS-REFERENCE TO RELATED APPLICATION

This application claims priority to Korean Patent Application No. 10-2023-0078172 filed in the Korean Intellectual Property Office on Jun. 19, 2023, the disclosure of which is incorporated herein by reference in its entirety.

### FIELD

This disclosure relates to a slurry composition for chemical mechanical polishing including a supramolecular compound (e.g., a supramolecular assembly), or an analog thereof, or a derivative thereof, which is an organic abrasive material, and a method of manufacturing a semiconductor device including, for example, chemical mechanical polishing by contacting a surface of a semiconductor substrate (also referred to as a substrate) or a surface of a layer formed on the substrate with a polishing pad using the same.

### BACKGROUND

Recently, with down-sizing of electronic devices and the resulting miniaturization of integrated circuits, various methods of forming a microstructure such as a metal wire having a width of several nanometers or a shallow trench isolation are being researched. In the step of forming the microstructure, a polishing process may be performed to create a planar and/or flat surface of the microstructure. The polishing process may include, for example, chemical mechanical polishing (CMP). The chemical mechanical polishing is performed by providing a polishing slurry including an abrasive between a semiconductor substrate and a polishing pad and then, contacting the semiconductor substrate or a layer formed on the substrate with the polishing pad to planarize the surface of the substrate or a surface of the layer formed on the substrate. When an abrasive material such as inorganic polishing particles is added to a slurry composition for the chemical mechanical polishing, this abrasive material may cause product defects according to polishing conditions.

### SUMMARY OF THE INVENTION

One aspect of the present disclosure is to provide a slurry composition for chemical mechanical polishing that may reduce or completely prevent scratches, may show a higher metal removal rate than an insulating layer such as silica, and/or may be easy to post-clean after a polishing process.

A slurry composition for chemical mechanical polishing (CMP) according to some embodiments of the present invention may include an organic abrasive material, wherein the organic abrasive material includes a supramolecular compound (e.g., a supramolecular assembly), an analog thereof, or a derivative thereof.

The supramolecular compound may have a structure in which several building blocks are self-assembled to form the structure, and the building blocks may have a chemical structure of a macrocyclic molecule or a polyethylene glycol.

The building blocks having the chemical structure of the macrocyclic molecule may include cucurbituril, calixarene, pillararenes, crown ether, or porphyrin.

The building blocks having the chemical structure of the polyethylene glycol may further include a hydrophobic group.

The building blocks having the chemical structure of the polyethylene glycol may include or may be composed of an ethylene glycol group and a hydrophobic group, and a molecular weight ratio of the ethylene glycol group and the hydrophobic group may be about 1:2 to about 1:8.

The hydrophobic group may include an alkyl group, an alkenyl group, an alkynyl group, an aromatic group, or a combination thereof.

The building blocks having the chemical structure of the polyethylene glycol may be represented by Chemical Formula 1.

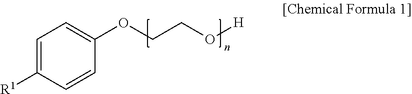

In Chemical Formula 1,
R¹ is a substituted or unsubstituted C1 to C20 alkyl group, and
n is an integer of 1 to 100.

The building blocks having the chemical structure of the polyethylene glycol may form a micelle structure. In some embodiments, the supramolecular assembly comprises or is a micelle. In some embodiments, the building blocks having the chemical structure of the polyethylene glycol may self-assemble with each other to form a micelle structure.

The building blocks may include or may be composed of the macrocyclic molecule and a molecule of another structure non-covalently bonded to the macrocyclic molecule. In some embodiments, the molecule of another structure may have a structure different from the macrocyclic molecule.

The molecule of another structure non-covalently bonded to the macrocyclic molecule may be an amine molecule.

The supramolecular compound may have a particle size of less than or equal to about 100 nm.

A content of an inorganic abrasive material in the slurry composition for CMP may be less than about 0.1 wt % based on a total amount of the slurry composition.

The slurry composition for CMP may be used for metal polishing.

The slurry composition for CMP may have a pH of about 2 to about 11.

The slurry composition for CMP may further include an oxidizing agent, a catalyst, an inhibitor, a chelator, a polishing booster, a stabilizer, a surfactant, or a combination thereof.

A slurry composition for chemical mechanical polishing (CMP) according to some embodiments of the present invention may include an organic abrasive material in an amount of about 0.1 wt % to about 10 wt % based on a total amount of the slurry composition for CMP, wherein the organic abrasive material includes a supramolecular compound (e.g., supramolecular assembly), an analog thereof, or a derivative thereof, and an inorganic abrasive material is excluded. In some embodiments, an inorganic abrasive material is not included in the slurry composition.

The slurry composition for CMP may have a pH of about 2 to about 5.

A method of manufacturing a semiconductor device according to some embodiments of the present invention may include arranging a semiconductor substrate and a polishing pad to face each other; supplying a slurry composition for CMP including a supramolecular compound (e.g., supramolecular assembly), an analog thereof, or a derivative thereof between the semiconductor substrate and the polishing pad; and contacting a surface of the semiconductor substrate or a surface of a layer formed on the semiconductor substrate with the polishing pad to perform polishing.

The slurry composition for CMP may polish metal wire(s) on or in the semiconductor substrate.

The metal wire(s) may include tungsten.

The slurry composition for CMP according to some embodiments of the present invention can improve polishing performance while reducing damage and shape deformation of structures of fine pitch. In particular, the slurry composition for CMP according to one aspect includes, as an organic abrasive material, a supramolecular compound in which building blocks (e.g., two or more of the same compound or molecule or two or more different compounds or molecules) are connected by a non-covalent bond (self-assembled) through a simple mixing process, which may allow for a scratch to not originally occur according to the particle size, elasticity to be adjusted according to the type and length of the building blocks, excellent polishing performance to be exhibited on various films, and/or, since a supramolecular compound can be produced by mixing the building blocks, the synthesis cost of organic abrasive materials can be low.

### BRIEF DESCRIPTION OF THE DRAWINGS

FIG. 1 is a view showing that several macrocyclic molecules self-assemble with each other as building blocks to form a supramolecular compound.

FIG. 2 is a view showing that compounds having a chemical structure of several polyethylene glycols are self-assembled into building blocks to form a supramolecular compound.

FIG. 3 is a view showing that a supramolecular compound having a structure in which several building blocks are self-assembled can be scratch-less or completely scratch-free when used as an organic abrasive material.

FIG. 4 is a perspective view illustrating a polishing apparatus capable of performing chemical mechanical polishing.

FIGS. 5 to 7 are cross-sectional views illustrating a method of manufacturing a semiconductor device according to some embodiments of the present invention.

FIG. 8 is a cross-sectional photograph of tungsten taken after polishing tungsten with the slurry composition for CMP according to Example 4.

FIG. 9 is a cross-sectional photograph of tungsten taken after polishing tungsten with the slurry composition for CMP according to Comparative Example 1.

### DETAILED DESCRIPTION

The present invention will be described more fully hereinafter with reference to the accompanying drawings, in which some example embodiments of the present invention are shown. As those skilled in the art would realize, the described embodiments may be modified in various different ways, all without departing from the scope of the present invention.

The drawings and descriptions are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “plane”, it means when the target part is viewed from above, and when referring to “cross section”, it means when viewing the cross section of the target portion vertically cut from the side.

As used herein, when a definition is not otherwise provided, “substituted” refers to replacement of hydrogen by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono a group, a carbonyl group, a carbamyl group, a thiol group, an ester group, an ether group, a carboxyl group or a salt thereof, a sulfonic acid group or a salt thereof, phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

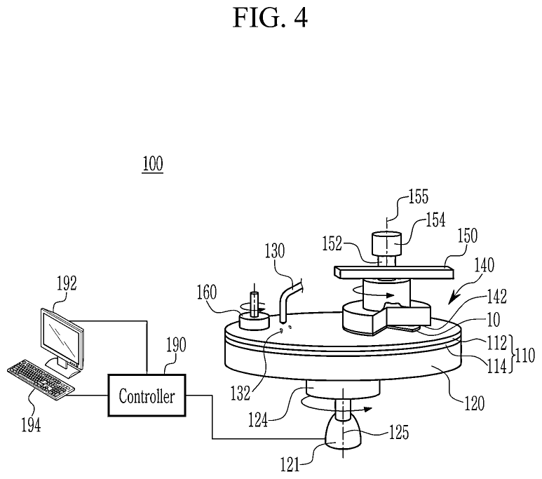

FIG. 4 is a perspective view illustrating a polishing apparatus 100 capable of performing chemical mechanical polishing.

Referring to FIG. 4, the polishing apparatus 100 includes a rotating disk-shaped platen 120 on which a polishing pad 110 is placed. The platen 120 is operable to rotate about an axis 125. For example, the motor 121 may rotate a drive shaft 124 to rotate the platen 120. The polishing pad 110 may be a polishing pad 110 having two or more layers including an outer polishing layer 112 and a softer backing layer 114.

The polishing apparatus 100 may include a slurry port 130 for dispensing an abrasive material 132 such as slurry toward the polishing pad 110 on the polishing pad 110. The polishing apparatus 100 may also include a polishing pad conditioner 160 for grinding the polishing pad 110 to maintain the polishing pad 110 in a consistent polishing state.

The polishing apparatus 100 includes at least one carrier head 140. The carrier head 140 may operate to hold the substrate 10 against the polishing pad 110. The carrier head 140 may control polishing parameters associated with each individual substrate, such as pressure.

In particular, the carrier head 140 may include a retaining ring 142 to retain the substrate 10 under the flexible membrane. The carrier head 140 may also include a plurality of independently controllable pressurizable chambers defined by the flexible membrane, which can apply independently controllable pressures on the flexible membrane and thus on relevant areas on the substrate 10.

The carrier head 140 is suspended from a support structure 150, for example a carousel or track, and is connected to a carrier head rotational motor 154 by a drive shaft 152 so that the carrier head is rotatable about an axis 155. Optionally, the carrier head 140 may vibrate laterally, for example. On a slider on the support structure (e.g., carousel) 150 or track, or by rotational vibration of the carousel itself. In operation, the platen 120 is rotated about its central axis 125, the carrier head 140 is rotated about its central axis 155, and they are translated laterally across the uppermost surface of the polishing pad.

Although only one carrier head 140 is shown in FIG. 4, two or more carrier heads may be provided to hold additional substrates so that the surface area of the polishing pad 110 can be efficiently used.

The polishing apparatus 100 also includes a control system for controlling rotation of the platen 120. The control system may include a controller 190 such as a general-purpose programmable digital computer, an output device 192 for output, for example, a monitor, and an input device 194 for input, for example, a keyboard.

In FIG. 4, the control system is shown as being connected only to the motor 121, but may also be connected to the carrier head 140 to adjust head pressure or rotational speed of the carrier head. Furthermore, the control system may be connected to the slurry port 130 to adjust the supply of the slurry.

Some embodiments of the present invention provide a slurry composition for chemical mechanical polishing (CMP) that can be used in the polishing apparatus 100.

The slurry composition for CMP includes an organic abrasive material.

According to some embodiments of the present invention, the slurry composition for CMP, which uses the organic abrasive material as an abrasive material, may solve the problem (CMP-induced defects) caused by particle refinement of a conventionally widely used inorganic abrasive material.

As a device becomes structurally more complex due to high density, three-dimensional structure, etc., and a wire line width is miniaturized down to a range of about 10 nm or less, CMP technology, one of the key processes for manufacturing a semiconductor, becomes more important and more necessary. Accordingly, as difficulties and requirements of a CMP process becomes higher, the CMP-induced defect problem, which has critical effects on a semiconductor manufacturing yield, is on the rise.

In the CMP process, micro and nano scratch defects are recognized as a chronic problem and known as damage caused by inorganic abrasive material particles. In addition, another problem such as dishing and erosion caused by local excessive polishing in a fine pattern region also has been reported to be closely related to the inorganic abrasive material.

As a minimum feature size of a wire (e.g., a semiconductor wire or a metal wire) is decreased, and the number of stacked layers is increased, the problems such as scratch defects, dishing, and erosion have fatal effects on a semiconductor mass production yield. Accordingly, in order to suppress these CMP defects, an abrasive with a smaller nanometer size than a design wire line width is desirable.

However, the inorganic material (silica, ceria, alumina, zirconia, etc.) used as a conventional abrasive material, when particles are refined to a size of several nm's, since new physical/chemical (nano size effect) phenomenon differing from classical mechanics works as a governing rule, may not only make it difficult (sometimes impossible) to control the CMP-induced defects but also sharply increase a management cost for suppressing generation of the defects and a defect inspection cost and deteriorate polishing performance, inevitably causing fatal difficulties in a semiconductor yield management.

Accordingly, the present inventors provide a novel organic abrasive material, specifically, “a nano-sized organic abrasive material having a specific molecular structure,” and more specifically, an organic supramolecular compound (or an analogue or a derivative thereof). The organic abrasive material may have no difference between atoms inside particles and atoms on the surface thereof due to characteristics of organic molecules, originally having no nano size effect.

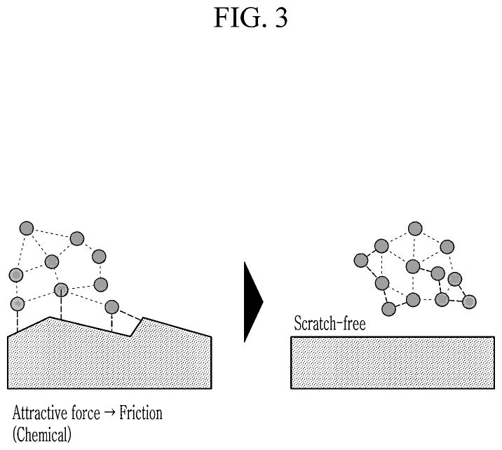

The organic abrasive material according to some embodiments is stable under strong acid and strong base conditions, structurally has very stable bonds and thus exhibit very excellent chemical and mechanical stability, and since an agglomerate is, if ever, formed by random packing, may exhibit no hardness increase. In addition, the organic abrasive material has a chemical interaction in a specific orientation, which may not generate scratch defects in principle, resulting in significantly reducing the dishing and erosion. In particular, compared with a polymer-based organic abrasive material which is conventionally used as an organic abrasive material, the organic abrasive material according to some embodiments may have a constant size and shape and thus may be used an excellent abrasive material. In some embodiments, the organic abrasive material according to some embodiments may have a uniform size and shape. FIG. 3 is a view showing that a supramolecular compound having a structure in which several building blocks are self-assembled can be scratch-less or completely scratch-free when used as an organic abrasive material. As shown in FIG. 3, since the organic abrasive material according to some embodiments has a chemical action only in a direction of the uneven surface of a material to be polished, just like removing dusts (unevenness) on the surface of a substrate by using a tape, uneven structures may be removed through chemical bonds to easily planarize the substrate.

### Organic Abrasive Material

The organic abrasive material includes a supramolecular compound (e.g., a supramolecular assembly), an analog thereof, or a derivative thereof. The supramolecular compound is a non-polymer, and has, for example, a self-assembled structure of several building blocks, and the building blocks may have a chemical structure of a macrocyclic molecule or a polyethylene glycol. In some embodiments, the supramolecular compound has a self-assembled structure that is formed from and/or provided by two or more building blocks, wherein the two or more building blocks may be the same or different. In some embodiments, the supramolecular compound has a self-assembled structure that is formed from and/or provided by two or more building blocks that have a chemical structure of a macrocyclic molecule or a polyethylene glycol. The supramolecular compound may be formed and/or provided (e.g., self-assembled) by including two or more building blocks together (e.g., in the same composition). In some embodiments, the supramolecular compound is a self-assembled structure of two or more of the same compound. In some embodiments, the supramolecular compound is a self-assembled structure of two or more of different compounds.

### (Macrocyclic Molecule Compound)

The building blocks having the chemical structure of the macrocyclic molecule may include, for example, cucurbituril, calixarene, pillararenes, crown ether, cyclodextrin, or porphyrin, but the present invention is not limited thereto. Non-limiting examples of cucurbiturils and analogs or derivatives thereof include, but are not limited to, those described in: Kim, J., et al . . . , J. Am. Chem. Soc. 2000, 122, 540-541; Day, A., et al., J. Org. Chem. 2001, 66, 8094-8100; Lee, J. W., et al., Cucurbituril Homologues and Derivatives: New Opportunities in Supramolecular Chemistry. Acc. Chem. Res. 2003, 36, 621-630; and Isaacs, L.; Park, S.-K.; Liu, S.; Ko, Y. H.; Selvapalam, N.; Kim, Y.; Kim, H.; Zavalij, P. Y.; Kim, G.-H.; Lee, H.-S.; Kim, K. J. Am. Chem. Soc. 2005, 127, 18000-18001. Non-limiting examples of cyclodextrins and analogs or derivatives thereof include, but are not limited to, those described in: Del Valle, E.M.M. Cyclodextrins and Their Uses: A Review. Process. Biochem. 2004, 39, 1033-1046; Crini, G. Review: A History of Cyclodextrins. Chem. Rev. 2014, 114, 10940-10975; and Morin-Crini, N.; Fourmentin, S.; Fenyvesi, É.; Lichtfouse, E.; Torri, G.; Fourmentin, M.; Crini, G. 130 Years of Cyclodextrin Discovery for Health, Food, Agriculture, and the Industry: A Review. Environ. Chem. Lett. 2021, 19, 2581-2617. Non-limiting examples of pillararenes and analogs or derivatives thereof include, but are not limited to, those described in: Ogoshi, T., et al., Pillar-Shaped Macrocyclic Hosts Pillar [n] arenes: New Key Players for Supramolecular Chemistry. Chem. Rev. 2016, 116, 7937-8002; Guo, F., et al., Recent progress in the research on the host-guest chemistry of pillar [n] arenes. Supramol. Chem. 2018, 30, 81-92; and Ogoshi, T.; Kakuta, T.; Yamagishi, T.-a. Applications of Pillar [n] arene-Based Supramolecular Assemblies. Angew. Chem. Int. Ed. 2019, 58, 2197-2206.

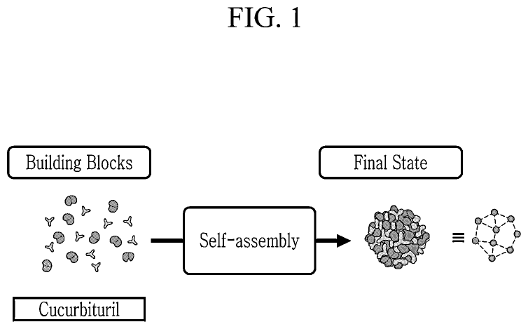

FIG. 1 is a view showing that several macrocyclic molecules self-assemble with each other as building blocks to form a supramolecular compound. Referring to FIG. 1, when a compound having the chemical structure of the macrocyclic molecule, such as cucurbituril, is mixed, a single agglomerate can be formed by self-assembly. Since the macrocyclic compound itself forms one macrocyclic molecule, it may further include molecules having other structures that are non-covalently bonded to the macrocyclic molecule. In some embodiments, the molecules having other structures may have structures different from macrocyclic molecule. That is, it may be a type of core-shell compound in which the non-covalently bonded molecule of another structure is used as a core and the macrocyclic molecule surrounding it is used as a shell. These core-shell compounds can also act as building blocks to form one supramolecular compound self-assembled with each other.

The molecules of other structures that are non-covalently bonded to the macrocyclic molecules capable of serving as the core may be, for example, amine molecules (e.g., compounds having functional groups such as *—NH₂, and *—NH₃⁺ at the terminal ends), but the present invention is not necessarily limited thereto.

(Compound having Chemical Structure of Polyethylene Glycol)

The building blocks having the chemical structure of polyethylene glycol may further include a hydrophobic group. The chemical structure of the polyethylene glycol itself may have both a hydrophilic group and a hydrophobic group. That is, in some embodiments, the building blocks having the chemical structure of polyethylene glycol may include both a hydrophilic group (e.g., ethylene glycol group) and a hydrophobic group. In some embodiments, the building blocks having the chemical structure of polyethylene glycol may include an ethylene glycol group and a hydrophobic group, and a molecular weight ratio of the ethylene glycol group and the hydrophobic group may be about 1:2 to about 1:8. For example, the building blocks having the chemical structure of polyethylene glycol may be composed of (e.g., consist of) an ethylene glycol group and a hydrophobic group, and a molecular weight ratio of the ethylene glycol group and the hydrophobic group may be about 1:2 to about 1:8.

For example, the hydrophobic group may include an alkyl group, an alkenyl group, an alkynyl group, an aromatic group, or a combination thereof.

When the molecular weight ratio of the hydrophilic ethylene glycol group and the hydrophobic alkyl, alkenyl, alkynyl and/or aromatic groups is controlled within the above range, selectivity of tungsten to oxide compared to the existing slurry composition for CMP can be greatly increased.

For example, the building blocks having the chemical structure of polyethylene glycol may be represented by Chemical Formula 1.

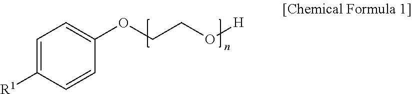

In Chemical Formula 1,
R¹ is a substituted or unsubstituted C1 to C20 alkyl group, and
n is an integer of 1 to 100.

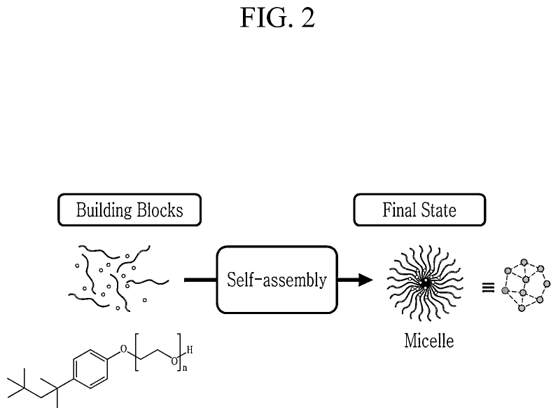

The macrocyclic molecule compound may form a type of core-shell structure through a non-covalent bond with a molecule (e.g., an amine molecule, etc.). FIG. 2 is a view showing that compounds having a chemical structure of several polyethylene glycols are self-assembled into building blocks to form a supramolecular compound. Referring to FIG. 2, the compound having the chemical structure of polyethylene glycol also may act as a building block and be self-assembled with each other, to form a similar micelle structure to the core-shell structure.

For example, the organic abrasive material may be included in an amount of about 0.1 wt % to about 25 wt %, for example, about 0.1 wt % to about 20 wt %, for example about 0.1 wt % to about 15 wt %, or for example about 0.1 wt % to about 10 wt % based on a total amount of the slurry composition for CMP according to some embodiments. Herein, the polishing performance may be further improved, while increasing metal selectivity to an oxide. Specifically, when the organic abrasive material is included in an amount of less than about 0.1 wt % based on a total amount of the composition, the content is so small as to have insufficient polishing effects, but when the organic abrasive material is included in an amount of greater than about 25 wt % based on a total amount of the composition, a polishing rate may be difficult to control.

For example, the supramolecular compound may have a particle diameter of less than or equal to about 100 nm, for example less than or equal to about 90 nm, for example less than or equal to about 80 nm, for example less than or equal to about 70 nm, for example less than or equal to about 60 nm, for example less than or equal to about 50 nm, for example less than or equal to about 40 nm, for example less than or equal to about 30 nm, for example less than or equal to about 20 nm, or for example less than or equal to about 10 nm. Considering that the particle size of the inorganic abrasive material is generally less than or equal to about 500 nm, the supramolecular compound has a very small particle size and may be effectively applied to structures with fine pitch. For example, since the longest diameter of cucurbituril is less than or equal to about 2 nm, it is expected that a particle size of the supramolecular compound using cucurbituril as a building block is very small.

The slurry composition for CMP according to some embodiments may include a very small amount of an inorganic abrasive material, wherein a content of the inorganic abrasive material may be less than about 0.1 wt %, for example less than about 0.08 wt %, for example less than about 0.05 wt %, for example less than about 0.03 wt %, for example less than about 0.01 wt %, for example less than about 0.008 wt %, for example less than about 0.005 wt %, for example less than about 0.003 wt %, for example less than about 0.001 wt %, for example less than about 0.0008 wt %, for example less than about 0.0005 wt %, for example less than about 0.0003 wt %, or for example less than about 0.0001 wt % based on a total amount of the slurry composition for CMP. The slurry composition for CMP according to some embodiments may include a very small amount of the inorganic abrasive material and has a very excellent effect of reducing various defects (e.g., particulate defect, scratch, etc.) due to the inorganic abrasive material and compared with a conventional slurry composition for CMP, excellent selectivity of a metal, particularly, tungsten to oxide. Furthermore, there may be almost no possibility of various problems in terms of process/management caused by inorganic particles (e.g., quality deterioration due to agglomeration of the inorganic abrasive material particles, slurry filter replacement cost, clogging of wastewater pipelines, complexity of wastewater treatment process, etc.)

The inorganic abrasive material may be any inorganic particle widely used in the slurry composition for CMP, for example, a metal oxide but is not limited thereto.

In some embodiments, the slurry composition for CMP may not include or may be devoid of an inorganic abrasive material. For example, the slurry composition for CMP may not include or may be devoid of metal oxide particles. For example, the slurry composition for CMP may not include any of silica, alumina, ceria, titania, zirconia, magnesia, germania (e.g., GeO₂), and mangania (e.g., Mn₂O₃).

Herein, “not including” a particle means that the particle is intentionally not added but does not mean that the particle is not present at all or is present below the detection limit. Accordingly, the slurry composition for CMP may include these particles in an amount of unavoidable impurities.

The inorganic abrasive material conventionally included in the slurry composition for CMP may damage a semiconductor device formed on a polishing target depending on polishing conditions. In other words, the inorganic abrasive material may damage a layer, a wire, a pattern, etc. formed on the polishing target or may not be sufficiently removed but remain after the polishing and thus cause contamination.

In addition, the inorganic abrasive material shortens a lifespan of the polishing pad 110 (refer to FIG. 4) used for the polishing, causing a replacement cost of the polishing pad 110 and an opportunity cost due to downtime for exchanging the polishing pad 110.

However, when the organic abrasive material is appropriately selected according to some embodiments, a sufficient polishing rate and high selectivity may be obtained without the inorganic abrasive material. When the inorganic abrasive material is not included in the slurry composition for CMP, there may be no cause for the damage and the contamination to the polishing target, and the polishing pad may be less worn out, reducing a manufacturing cost. In addition, the manufacturing cost may be further reduced, since the slurry composition for CMP itself becomes less expensive.

The slurry composition for CMP according to some embodiments may also include no dispersion stabilizer. As described above, since the slurry composition for CMP according to some embodiments does not include an inorganic abrasive material, a dispersion stabilizer generally added to ensure good dispersion of the inorganic abrasive material may not be necessary.

For example, the slurry composition for CMP includes none of ethylene oxide, ethylene glycol, glycol distearate, glycol monostearate, glycol polymerate, glycol ethers, alcohols containing alkylamines, compounds containing polymerate ethers, vinyl pyrrolidone, celluloses, and ethoxylates as a dispersion stabilizer. Specifically, the slurry composition for CMP may include none of diethylene glycol hexadecyl ether, decaethylene glycol hexadecyl ether, diethylene glycol octadecyl ether, diethylene glycol octadecyl ether, eicosaethylene glycol octadecyl ether, diethylene glycol oleyl ether, decaethylene glycol oleyl ether, decaethylene glycol octadecyl ether, nonylphenol polyethylene glycol ether, ethylenediamine tetrakis (ethoxylate-block-propoxylate) tetrol, ethylenediamine tetrakis (propoxylate-block-ethoxylate) tetrol, polyethylene-block-poly (ethylene glycol), polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylene sorbitan monolaurate, sorbitan monopalmitate, FS-300 nonionic fluorosurfactant, FSN nonionic fluorosurfactant, FSO nonionic ethoxylated fluorosurfactant, vinyl pyrrolidone, 2,4,7,9-tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, and polyoxyethylene isooctylcyclohexyl ether as a dispersion stabilizer.

### pH Adjusting Agent

For example, the pH of the slurry composition for CMP may be achieved or maintained by any suitable means in consideration of any polishing rate, dispersion stability, and the like. For example, the pH of the slurry composition for CMP may be, for example, about 2 to about 11, and within the above range, about 2 to about 8, about 2 to about 7, about 2 to about 6, or about 2 to about 5. When the pH of the slurry composition for CMP is controlled within the above range, polishing performance for metal, specifically tungsten, can be optimized. More specifically, when the pH of the slurry composition for CMP is controlled to about 2 to about 5, polishing performance for metals such as tungsten can be improved, and when the pH of the slurry composition for CMP is controlled to about 6 to about 11, polishing performance for non-metal dielectrics may be improved.

An acid solution and an alkali solution may be appropriately used to control the pH of the slurry composition for CMP as needed. In some embodiments, the pH adjusting agent may include, for example, an acid solution such as sulfuric acid, phosphoric acid, hydrochloric acid, nitric acid, carboxylic acid, maleic acid, malonic acid, citric acid, oxalic acid, tartaric acid, and/or an alkaline solution such as calcium hydroxide, potassium hydroxide, ammonium hydroxide, sodium hydroxide, magnesium hydroxide, triethylamine, tetramethylammonium hydroxide, and ammonia, but is not limited thereto. The pH adjusting agent may be included in the slurry composition for CMP in an amount such that the pH of the slurry composition for CMP has a predetermined range (e.g., a desired range), and is not particularly limited.

For example, the slurry composition for CMP may further include a carrier, an oxidizing agent, a catalyst, an inhibitor, a chelator, a polishing booster, a stabilizer, a surfactant, or a combination thereof.

### Carrier (Solvent)

The carrier may be any liquid capable of substantially uniformly dispersing the organic abrasive material or the organic polishing booster, and is not particularly limited. The carrier may be an aqueous solvent or an organic solvent.

In some embodiments, the carrier may include, for example, water, deionized water, ultrapure water, an alcohol (for example, propenyl alcohol, isopropyl alcohol, ethanol, 1-propanol, methanol, 1-hexanol, etc.), aldehyde (for example, formaldehyde, acetaldehyde, etc.), ester (for example, ethyl formate, propyl formate, ethyl acetate, methyl acetate, methyl lactate, butyl lactate, ethyl lactate, etc.), ketone (for example, acetone, diacetone alcohol, methyl ethyl ketone, etc.), dimethyl sulfoxide (DMSO), tetrahydrofuran, dioxane, diglyme, amide (for example, N,N-dimethyl formamide, dimethylimidazolidinone, N-methylpyrrolidone, etc.), polyhydric alcohol and a derivative thereof (for example, ethylene glycol, glycerol, diethylene glycol, diethylene glycol monomethylether, etc.), a nitrogen-containing organic compound (for example, acetonitrile, amylamine, isopropylamine, imidazole, dimethylamine, etc.), or a mixture thereof.

A content of the carrier may be a balance amount except for the above-described organic abrasive material, the pH adjusting agent, and other components described later.

### Surfactant

The slurry composition for CMP may further include a surfactant, if necessary. The surfactant may be appropriately selected from a nonionic surfactant, a cationic surfactant, an anionic surfactant, and an amphoteric surfactant.

Examples of the nonionic surfactant may include polyoxyethylenealkylether such as polyoxyethylenelaurylether, or polyoxyethylenestearylether; polyoxyethylene alkylphenylethers such as polyoxyethyleneoctylphenylether, or polyoxyethylene nonylphenyl ether; sorbitan higher fatty acid esters such as sorbitan monolaurate, sorbitan monostearate, or sorbitan trioleate; polyoxyethylenesorbitan higher fatty acid esters such as polyoxyethylenesorbitanmonolaurate; polyoxyethylene higher fatty acid esters such as polyoxyethylenemonolaurate or polyoxyethylenemonostearate; for example, glycerine higher fatty acid esters such as oleic acidmonoglyceride, stearic acidmonoglyceride, and the like; polyoxyalkylenes such as polyoxyethylene, polyoxypropylene, or polyoxybutylene; and block copolymers thereof.

Examples of the cationic surfactant may include alkyl trimethyl ammonium chloride, dialkyl dimethyl ammonium chloride, a benzalkonium chloride salt, and alkyl dimethyl ammonium ethosulfate.

Examples of the anionic surfactant may include carboxylate such as sodium laurate, sodium oleate, N-acyl-N-methylglycine sodium salt, sodium polyoxyethylene lauryl ether carboxylate; sulfonic acid salts such as sodium dodecylbenzenesulfonate, dialkylsulfo succinic acid ester salts, sodium dimethyl-5-sulfoisophthalate; sulfuric acid ester salts such as sodium lauryl sulfate, sodium polyoxyethylene lauryl ether sulfate, or sodium polyoxyethylene nonylphenyl ether sulfate; phosphoric acid ester salts such as sodium polyoxyethylene lauryl phosphate, or sodium polyoxyethylene nonylphenyl ether phosphate; and the like.

Examples of the amphoteric surfactant may include carboxybetaine type surfactants, aminocarboxylic acid salts, imidazolinium betaine, lecithin, and alkylamine oxides.

The surfactant may be included in the weight of about 0.001 wt % to about 0.5 wt % in the slurry composition for CMP.

### Planarizing Agent

The slurry composition for CMP may further include a planarizing agent (also referred to as a leveling agent) to reduce unevenness of the surface to be polished, if necessary.

Non-limiting examples of the leveling agent may include ammonium chloride, ammonium lauryl sulfate, polyethylene glycol, polyoxyethylene alkyl ether sulfate triethanolamine, polyvinylpyrrolidone, polyacrolein, and the like.

The planarizing agent may be included in an amount of about 0.1 wt % to about 1 wt % in the slurry composition for CMP.

### Oxidizing Agent

The slurry composition for CMP may further include an oxidizing agent. The oxidizing agent oxidizes the surface of a film (e.g., a metal film) to change the film (e.g., the metal film) into a state easily oxidized. Non-limiting examples of the oxidizing agent may include organic peroxides such as hydrogen peroxide, peracetic acid, perbenzoic acid, or tert-butyl hydroperoxide; permanganate compounds such as potassium permanganate; dichromic acid compounds such as potassium dichromate; halogen acid compounds such as potassium iodate; nitric acid compounds such as nitric acid and iron nitrate; perhalogen acid compounds such as perchloric acid; persulfates such as sodium persulfate, potassium persulfate, or ammonium persulfate; percarbonates such as sodium percarbonate or potassium percarbonate; urea peroxide; and heteropoly acids.

In addition, an auxiliary oxidizing agent such as iron nitrate oxide hydrate, which can assist the oxidizing action of the oxidizing agent, may be used together with the oxidizing agent.

### Stabilizer

The slurry composition for CMP may further include a stabilizer that may reduce or prevent rapid decomposition of the oxidizing agent and keeps it stable during polishing.

### Corrosion Inhibitors

The slurry composition for CMP may further include a corrosion inhibitor that protects the surface to be polished from corrosion, if necessary. When the corrosion inhibitor is further included, recesses, erosion, roughness, and the like can be improved.

Non-limiting examples of the corrosion inhibitor may include triazole and a derivative thereof, benzene triazole and a derivative thereof. The triazole derivative may include, but is not limited to, an amino-substituted triazole compound and a bi-amino-substituted triazole compound.

The corrosion inhibitor may be included in a weight of about 0.001 wt % to about 0.15 wt % in the slurry composition for CMP. In some embodiments, the amount of the corrosion inhibitor may be about 0.0025 wt % to about 0.1 wt % or about 0.005 wt % to about 0.05 wt %.

The slurry composition for CMP may be applied when forming various structures, and may be applied, for example, to a polishing process of a conductor such as metal wire(s) or a polishing process of an insulator such as shallow trench isolation (STI) or an insulating film. For example, the slurry composition for CMP may be used to polish a conductive layer, an insulating layer, and/or a semiconductor layer which have a surface with a charge on or in a semiconductor substrate, and may be for example, used to polish a conductive layer, an insulating layer and/or a semiconductor layer which have a generally negatively charged surface.

For example, the slurry composition for CMP may be used to polish a conductor such as a metal wire on or in a semiconductor substrate, and may be used to polish a conductor such as copper (Cu), tungsten (W), or an alloy thereof.

Hereinafter, an example of a method for manufacturing a semiconductor device using the aforementioned slurry composition for CMP will be described.

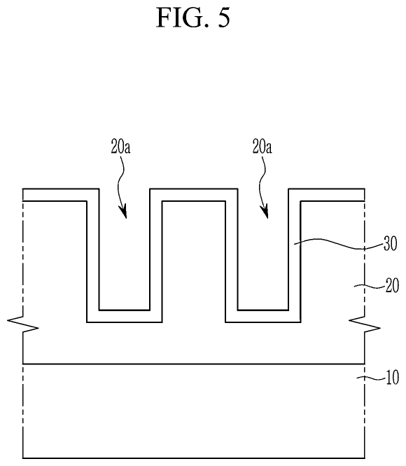

FIGS. 5 to 7 are cross-sectional views illustrating a method of manufacturing a semiconductor device according to some embodiments of the present invention.

Referring to FIG. 5, an interlayer insulating layer 20 is formed on the semiconductor substrate 10. The interlayer insulating layer 20 may include, for example, oxide, nitride, and/or oxynitride. Next, the interlayer insulating layer 20 is etched to form an opening (e.g., a trench) 20a. The trench 20a may have a width of less than or equal to about 10 nm. Subsequently, a barrier layer 30 is formed on the wall surface of the trench 20a. The barrier layer 30 may include, for example, Ti and/or TiN, but is not necessarily limited thereto.

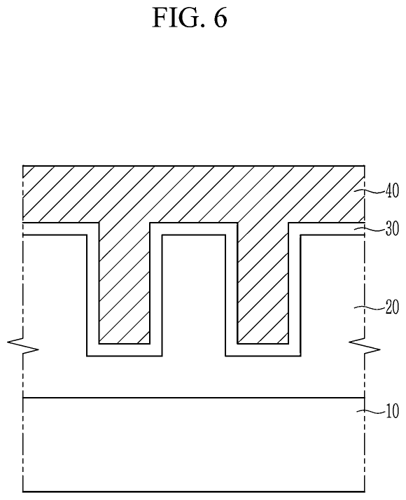

Referring to FIG. 6, a metal layer 40 is formed by filling the trench 20a with a metal such as tungsten (W).

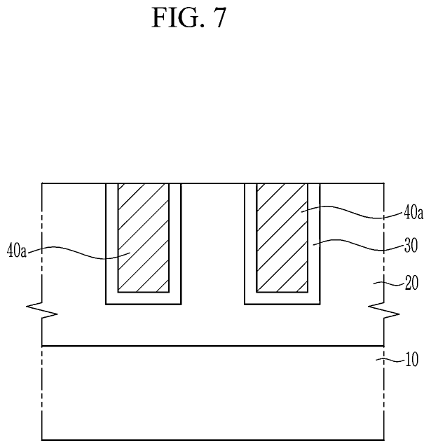

Referring to FIG. 7, the buried metal layer 40a is formed by planarizing the surface of the metal layer 40 to match the surface of the interlayer insulating layer 20. The planarizing may be performed by chemical mechanical polishing using chemical mechanical polishing (CMP) equipment, and the aforementioned slurry composition for CMP may be used. This will be described later. For example, when the barrier layer 30 is a TiN layer and the metal layer 40 is a W layer, the higher the polishing selectivity of TiN to W of the slurry composition for CMP, the better, and for example, higher than about 50:1, the better.

The planarizing for forming the buried metal layer 40a will be described below. The planarizing may be performed by chemical mechanical polishing using chemical mechanical polishing (CMP) equipment as described above.

The chemical mechanical polishing equipment, as described above, may include, for example, a lower base; a platen rotatably provided on the upper surface of the lower base; a polishing pad disposed on the platen; a pad conditioner; and at least one CMP slurry composition supply device disposed adjacent to the polishing pad to supply (e.g., apply) the CMP slurry composition to the polishing pad (refer to FIG. 4).

The platen may be rotatably provided on the surface of the lower base. For example, the platen may receive rotational power from a motor disposed in the lower base. Accordingly, the platen may rotate based on an imaginary axis of rotation perpendicular to the surface of the platen. The imaginary axis of rotation may be perpendicular to the surface of the lower base.

The platen may have one or more supply lines through which liquid may be injected and discharged. Water may be injected and discharged into the platen through a supply line, and the temperature of the platen may be controlled by the injected water. For example, cooling water may be injected into and discharged into the platen through a supply line, thereby lowering the temperature of the overheated platen. For example, hot water may be injected into and discharged into the platen through a supply line, thereby inducing a temperature increase of the platen.

The polishing pad may be placed on the surface of the platen to be supported by the platen. The polishing pad can rotate together with the platen. The polishing pad may have a rough polishing surface. Such a polishing surface may directly contact the semiconductor substrate 10 or a layer formed on the semiconductor substrate 10 to mechanically polish the surface of the semiconductor substrate 10 or a surface of the layer formed on the semiconductor substrate 10. The polishing pad may be a porous material having a plurality of microspaces, and the plurality of microspaces may include a slurry composition for CMP.

The pad conditioner may be disposed adjacent to the polishing pad and maintain the state of the polishing surface so that the surface of the semiconductor substrate 10 or the surface of the layer formed on the semiconductor substrate 10 is effectively polished while the polishing process is performed.

The CMP slurry composition supply device may be disposed adjacent to the polishing pad, and may supply the slurry composition for CMP to the polishing pad. The CMP slurry composition supply device may include a nozzle capable of supplying the slurry composition for CMP onto a polishing pad during a polishing process and a voltage supply unit capable of applying a predetermined voltage to the nozzle. The slurry composition for CMP in the nozzle may be charged and discharged toward the polishing pad by the voltage applied from the voltage supply unit. The CMP slurry composition supply device can supply the aforementioned slurry composition for CMP.

In some embodiments, the chemical mechanical polishing may be performed by arranging a semiconductor substrate 10 and a polishing pad to face each other; supplying the slurry composition for CMP from the CMP slurry composition supply device between the semiconductor substrate 10 and the polishing pad; and contacting the surface of the semiconductor substrate 10 or the surface of the layer formed on the semiconductor substrate 10 with the polishing pad to perform polishing.

For example, the slurry composition for CMP may be used to polish conductors such as metal wire(s) on or in a semiconductor substrate, and may be used to polish conductors such as copper (Cu), tungsten (W) or alloys thereof, but is not necessarily limited thereto.

For example, the supplying the slurry composition for CMP may be supplied at a rate of, for example, about 10 ml/min to about 100 ml/min.

The polishing may be performed through mechanical friction by bringing the surface of the semiconductor substrate 10 or the surface of the layer formed on the semiconductor substrate 10 into contact with the polishing pad and rotating the polishing pad. For example, a pressure of about 1 psi to about 5 psi may be applied in the process of performing polishing.

For example, when the metal layer 40 and the buried metal layer 40a include tungsten, the higher the ratio of the material removal rate (MRR) of tungsten relative to the etching rate (ER) of tungsten by the slurry composition for CMP, the better, and for example the ratio may be greater than or equal to about 1, greater than or equal to about 2, greater than or equal to about 3, greater than or equal to about 4, greater than or equal to about 5, greater than or equal to about 6, greater than or equal to about 7, greater than or equal to about 8, greater than or equal to about 9, greater than or equal to about 10, greater than or equal to about 11, greater than or equal to about 12, greater than or equal to about 13, greater than or equal to about 14, greater than or equal to about 15, greater than or equal to about 16, greater than or equal to about 17, greater than or equal to about 18, greater than or equal to about 19, or greater than or equal to about 20, within the above the range, about 1 to about 20, about 2 to about 20, about 3 to about 20, about 3 to about 19, about 3 to about 18, or about 3 to about 17.

By having the ratio of the polishing rate to the etching rate as described above, it is possible to reduce the etching rate of the metal wire, secure the planarity of the semiconductor substrate after the polishing process, and solve problems such as recesses.

As mentioned above, although example embodiments have been described, various additions, omissions, substitutions, and changes may be made without being limited to the example embodiments described above. Further, it is possible to form other embodiments by combining elements in different embodiments.

Hereinafter, the configuration and effects of the present invention will be described in more detail with specific examples and comparative examples, but these examples are only intended to more clearly understand the present invention and are not intended to limit the scope of the present invention.

### (Preparation of CMP Slurry Composition)

### Comparative Example 1

1 wt % of silica (a primary particle diameter of 15 nm, PL-1, FUSO Chemical Co., Ltd.), 0.06 wt % of benzotriazole, 0.4 wt % of ammonium dihydrogen phosphate, 0.5 wt % of triammonium citrate, 1.6 wt % of hydrogen peroxide, and a balance amount of water were included to prepare slurry.

### Example 1

2.5 wt % of cucurbituril, 2.4 wt % of hydrogen peroxide, 0.32 wt % of malonic acid, and 0.0013 wt % of ferric nitrate nonahydrate (FeNO₃·9H₂O) were mixed and then, treated with a 5 M nitric acid solution to adjust pH to 2.0. The cucurbituril was synthesized in a known synthesis method (J. Kim et al., J. Am. Chem. Soc., 2000, 122, 540.).

### Example 2

A slurry composition for CMP was prepared in the same manner as in Example 1 except that Triton X-102 (Dow) was used instead of the cucurbituril.

### Example 3

A slurry composition for CMP was prepared in the same manner as in Example 2 except that the ferric nitrate nonahydrate (FeNO₃·9H₂O) was used in an amount of 0.002 wt % instead of the 0.0013 wt %.

### Example 4

A slurry composition for CMP was prepared in the same manner as in Example 2 except that 0.06 wt % of benzotriazole was added.

### (Evaluation)

Pad: KPX IT-3000

CMP equipment: GnP Technology Poly 762

Object to be polished: 12-inch tungsten non-patterned wafer, 12-inch silicon oxide non-patterned wafer

Process conditions: head 4.2 psi, retainer ring 6.5 psi, head 121 rpm, pad

119 rpm, flow rate 180 sccm, ex-situ conditioning, 60 sec polishing

Each of the compositions according to Examples 1 to 4 and Comparative

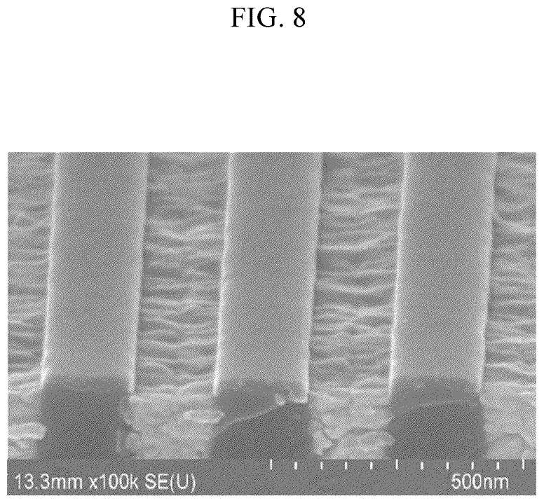

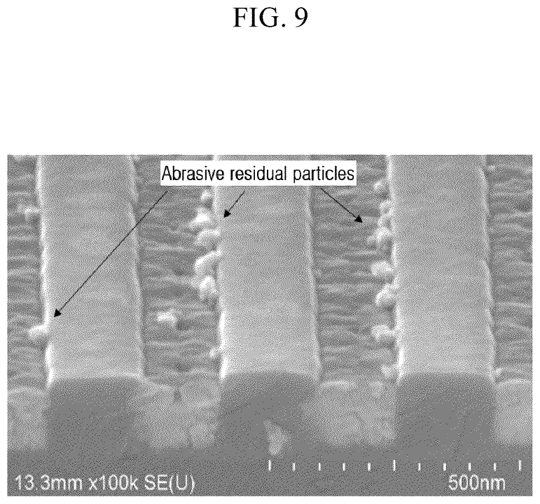

Example 1 was evaluated with respect to polishing performance under the conditions, and the results are shown in Table 1 and FIGS. 8 and 9.

TABLE 1

| | Tungsten | | Silicon oxide | |
|---|---|---|---|---|
| | polishing rate | Uniformity | polishing rate | Selective |
| | (Å/min) | (%) | (Å/min) | ratio |
| Comparative | 4288 | 4.6 | 45 | 95:1 |
| Example 1 | | | | |
| Example 1 | 4302 | 9.7 | 1 | 2151:1 |
| Example 2 | 5532 | 4.5 | 1 | 2766:1 |
| Example 3 | 4933 | 2.1 | 1 | 2496:1 |
| Example 4 | 3130 | 8.6 | 1 | 1565:1 |

As shown in Table 1, when the slurry composition for CMP according to the embodiments was used to polish a tungsten (W) film, superbly excellent polishing performance was achieved, compared with the slurry composition for CMP according to the comparative example. Particularly, referring to FIGS. 8 and 9, when the slurry composition for CMP according to the embodiments was used to polish a tungsten (W) film, an abrasive material after the polishing was less left than when the slurry composition for CMP according to the comparative example was used, significantly reducing product defects.

While this invention has been described with some example embodiments, it is to be understood that the present invention is not limited to the embodiments described herein. Rather, those embodiments are described to cover various modifications and equivalent arrangements included within the scope of the appended claims.

What is claimed is:

1. A slurry composition comprising:
an organic abrasive material,
wherein the organic abrasive material includes a supramolecular compound, an analog thereof, or a derivative thereof.

2. The slurry composition of claim 1, wherein
the supramolecular compound has a self-assembled structure that is formed from two or more building blocks, wherein the two or more building blocks have a chemical structure of a macrocyclic molecule or a polyethylene glycol.

3. The slurry composition of claim 2, wherein
the two or more building blocks have the chemical structure of the macrocyclic molecule, and wherein the macrocyclic molecule comprises cucurbituril, calixarene, pillararenes, crown ether, or porphyrin.

4. The slurry composition of claim 2, wherein
the two or more building blocks have the chemical structure of the polyethylene glycol, and wherein the polyethylene glycol comprises a hydrophobic group.

5. The slurry composition of claim 4, wherein the polyethylene glycol further comprises an ethylene glycol group, and wherein the polyethylene glycol has a molecular weight ratio of the ethylene glycol group and the hydrophobic group of about 1:2 to about 1:8 (ethylene glycol group: hydrophobic group).

6. The slurry composition of claim 4, wherein
the hydrophobic group comprises an alkyl group, an alkenyl group, an alkynyl group, an aromatic group, or a combination thereof.

7. The slurry composition of claim 4, wherein
the polyethylene glycol has a structure of Chemical Formula 1: 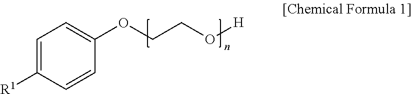
wherein:
R¹ is a substituted or unsubstituted C1 to C20 alkyl group, and
n is an integer of 1 to 100.

8. The slurry composition of claim 4, wherein
the two or more building blocks have the chemical structure of the polyethylene glycol, and wherein the two or more building blocks self-assemble to form a micelle structure.

9. The slurry composition of claim 2, wherein
the two or more building blocks have the chemical structure of the macrocyclic molecule, and wherein the macrocyclic molecule comprises a molecule that has a structure different from the macrocyclic molecule, and the molecule is non-covalently bound to the macrocyclic molecule.

10. The slurry composition of claim 9, wherein
the molecule that is non-covalently bound to the macrocyclic molecule is an amine molecule.

11. The slurry composition of claim 1, wherein
the supramolecular compound has a particle size of less than or equal to about 100 nm.

12. The slurry composition of claim 1, wherein
a content of an inorganic abrasive material in the slurry composition is less than about 0.1 wt % based on a total amount of the slurry composition.

13. The slurry composition of claim 1, wherein
the slurry composition is configured for metal polishing.

14. The slurry composition of claim 1, wherein
the slurry composition has a pH of about 2 to about 11.

15. The slurry composition of claim 1, further comprising an oxidizing agent, a catalyst, an inhibitor, a chelator, a polishing booster, a stabilizer, a surfactant, or a combination thereof.

16. A slurry composition comprising:
about 0.1 wt % to about 10 wt % of an organic abrasive material based on a total amount of the slurry composition,
wherein the organic abrasive material includes a supramolecular compound, an analog thereof, or a derivative thereof, and
wherein the slurry composition is devoid of an inorganic abrasive material.

17. The slurry composition of claim 16, wherein
the slurry composition has a pH of about 2 to about 5.

18. A method of manufacturing a semiconductor device, the method comprising:
providing a semiconductor substrate and a polishing pad that face each other;
supplying a slurry composition including a supramolecular compound, an analog thereof, or a derivative thereof between the semiconductor substrate and the polishing pad; and
contacting a surface of the semiconductor substrate or a surface of a layer formed on the semiconductor substrate with the polishing pad to perform polishing.

19. The method of claim 18, wherein
the slurry composition polishes a metal wire on or in the semiconductor substrate.

20. The method of claim 19, wherein
the metal wire includes tungsten.
